(19) United States
(12) Patent Application Publication
(10) Pub. No.: US 2025/0351317 A1
(43) Pub. Date: Nov. 13, 2025

(54) Electrical Devices

(71) Applicant: Frank VOGELSANG, Muelhausen (DE)

(72) Inventor: Frank VOGELSANG, Muelhausen (DE)

(21) Appl. No.: 18/870,499

(22) PCT Filed: May 15, 2023
(86) PCT No.: PCT/EP2023/062970

§ 371 Date: Nov. 29, 2024

(30) Foreign Application Priority Data
Jun. 1, 2022 (DE) 20 2022 103 105.3

(51) Int. Cl. H05K 9/00; H01B 7/08

(52) U.S. Cl. CPC H05K 9/0098; H01B 7/08

(57) ABSTRACT

The invention relates to electric devices by which electrical signals are transmitted, such as e.g. a ribbon cable, an integrated semiconductor component, an electrical circuit arrangement or another electrical cable.

The invention relates to electric devices by which electrical signals are transmitted, such as e.g. a ribbon cable, an integrated semiconductor component, an electrical circuit arrangement or another electrical cable.

Electronic apparatuses that are used today operate overwhelmingly using electrical signals, i.e. using electrical voltages and currents, that are relatively small and therefore sensitive to interference. Nevertheless, a high quality of the signal transmission is important in many fields. For example in the field of hi-fi apparatuses, even slight external interference signals already generate undesired noise and interference components on the useful signals. In addition, contemporary electronic switching circuits also have an inherent noise, which is not to be ignored, by which the useful signals are adversely affected.

The invention is based on the object of specifying an option, which is simple to produce, for reducing the signal noise in an electric device transmitting electrical signals.

This object is achieved by a device having at least one ribbon cable which has an electrical conductor or a plurality of electrical conductors which are arranged next to one another in a width direction of the ribbon cable and insulated with respect to one another and which are sheathed by insulating material, and at least one flat-tape magnetic strip and/or at least one magnetic film, which is arranged on at least one flat side of the ribbon cable and extends over at least a portion of the longitudinal extent of the ribbon cable or the entire length of the ribbon cable.

The invention is also suitable for other electric devices or electrical components which transmit electrical signals.

The magnetic field generator used is therefore at least one flat-tape magnetic strip and/or a magnetic film. Such elements can be acquired commercially. The flat-tape magnetic strip and/or the magnetic film may have individual strip-shaped magnets which are arranged next to one another and which are designed as permanent magnets of different polarity and arranged next to one another in an alternating manner. The flat-tape magnetic strip or the magnetic film may have a substrate in which the individual magnets, which are arranged next to one another, are embedded.

Here, the magnetic field generators, i.e. the flat-tape magnetic strip or the magnetic film, can be placed on the outside of the ribbon cable and for example adhesively bonded to the same. It is also possible to produce the ribbon cable directly in an integrated production process together with the magnetic field generator, wherein the magnetic field generator is then applied directly on the ribbon cable.

In a further advantageous variant, the electrical conductor or conductors of the ribbon cable can be embedded in a substrate, in particular a magnetic tape, of the flat-tape magnetic strip and/or the magnetic film. Here also, the flat-tape magnetic strip and/or the magnetic film can extend over at least a portion of the longitudinal extent of the ribbon cable or the entire length of the ribbon cable. In this manner, the ribbon cable can be produced using the flat-tape magnetic strip or the magnetic film in an integrated production process without the flat-tape magnetic strip or the magnetic film having to be applied afterward.

According to an advantageous embodiment of the invention, provision is made for at least one flat-tape magnetic strip and/or one magnetic film to be arranged on both flat sides of the ribbon cable and extend over at least a portion of the longitudinal extent of the ribbon cable or the entire length of the ribbon cable. As a result of this, the advantageous shielding effects of the invention can be improved even further.

According to an advantageous embodiment of the invention, provision is made for the electrical conductor or conductors in the ribbon cable to be formed from a flat sheet-metal material which has a substantially larger width than thickness. The electrical conductor or conductors therefore have a larger dimension in the width direction of the ribbon cable than the direction of the thickness of the ribbon cable. The ribbon cable can in particular have only one continuously wide electrical conductor made from flat material. The sheet-metal material suitable for the electrical conductor or conductors is in particular silver, copper, gold or an alloy thereof.

According to an advantageous embodiment of the invention, provision is made for the electrical conductor or conductors to be sheathed in each case by an insulation layer formed by a lacquer. For this, e.g. a transformer lacquer can be used, similarly to enameled copper wire. The lacquer insulation layer can be applied onto the respective electrical conductor e.g. by means of a coating method.

The object mentioned in the introduction is additionally achieved by an integrated semiconductor component having a housing made from plastic or another insulating material, in which a semiconductor circuit is embedded, and a multiplicity of connecting pins or connecting pads which can be contacted on the outside of the housing, wherein at least one flat-tape magnetic strip and/or at least one magnetic film, which extends over a portion of the upper side of the housing or the entire upper side of the housing, is arranged on the upper side of the housing. The flat-tape magnetic strip and/or the magnetic film can here be applied directly on the outer surface of the housing.

According to an advantageous embodiment of the invention, provision is made for at least one flat-tape magnetic strip and/or one magnetic film, which extends over a portion of the underside of the housing or the entire underside of the housing, to be arranged on the underside of the housing.

The object mentioned in the introduction is additionally achieved by an electrical circuit arrangement having at least one printed circuit board and electrical and/or electronic components that are arranged thereon, wherein at least one flat-tape magnetic strip and/or at least one magnetic film, which extends over a portion of the flat extent of the printed circuit board or over the entire flat extent of the printed circuit board, is arranged on the electrical circuit arrangement.

According to an advantageous embodiment of the invention, provision is made for at least one flat-tape magnetic strip and/or one magnetic film, which extends over a portion of the flat extent of the printed circuit board or over the entire flat extent of the printed circuit board, to be arranged on the electrical circuit arrangement on both sides.

The object mentioned in the introduction is additionally achieved by an electrical power outlet strip having a housing, a plurality of power outlets having electrical contacts and connecting lines which connect contacts of the power outlets to one or more supply lines and are arranged in the housing, wherein at least one flat-tape magnetic strip and/or at least one magnetic film, which extends over a portion of the flat extent of the connecting line or over the entire flat extent of the connecting line, is arranged on one, several or all connecting lines in each case. In this manner, it is also possible to eliminate interference from an electrical power outlet strip or to protect same from radiated interference. The connecting lines can for example be designed as flat conductors, e.g. in the form of strip-shaped sheet-metal parts, on which at least one flat-tape magnetic strip and/or at least one magnetic film is arranged on one or both opposite surface sides. The power outlet strip can in particular be designed as a power outlet strip for a commercial alternating-current supply, i.e. for the 220 V or 110 V grid.

According to an advantageous embodiment of the invention, provision is made for the power outlet strip to have one or more sleeve-shaped bodies, wherein a sleeve-shaped body in each case extends in an annular manner around the electrical contacts of a respective power outlet, wherein the sleeve-shaped body consists entirely or partly of a permanent magnet, in particular of at least one flat-tape magnetic strip and/or at least one magnetic film. Here, the sleeve-shaped body can have at least one permanent magnet over its entire circumference and/or over its entire longitudinal extent.

Furthermore, the object mentioned in the introduction is achieved by an electrical cable having at least one electrical conductor and an internal insulation layer sheathing the electrical conductor, characterized by one or both of the following features a), b):
a) a ferrofluid is arranged inside the inner insulation layer on the at least one electrical conductor,
b) the inner insulation layer is sheathed by an additional outer insulation layer, wherein a ferrofluid is arranged between the inner insulation layer and the outer insulation layer.

According to an advantageous embodiment of the invention, provision is made for a magnet arrangement to be arranged along the longitudinal extent on the electrical cable, wherein the magnet arrangement in each case encloses the outer insulation layer or, if this is not present, encloses the inner insulation layer. The magnet arrangement can have e.g. a multiplicity of ring magnets, at least one flat-tape magnetic strip and/or a magnetic film.

The invention is therefore suitable both for single-core electrical cables, for which an outer insulation layer is not yet additionally present, and for single-core or multi-core electrical cables having the outer insulation layer mentioned. The electrical conductors can be designed as solid single conductors or as stranded conductors. A ferrofluid is a liquid that reacts to magnetic fields without solidifying in the process. A ferrofluid can consist e.g. of magnetic particles that are relatively small, e.g. only a few nanometers in size, and are suspended in a carrier liquid. The particles can consist e.g. of iron, magnetite and/or cobalt. The particle size can be e.g. smaller than a magnetic domain, e.g. in the order of magnitude of 5-10 nm in diameter.

The object mentioned in the introduction is additionally achieved by an electrical connector for connection to a mating connector that is assigned as a mating part, particularly a power outlet of a power outlet strip of the previously explained type, wherein the electrical connector has one or more plug contacts, characterized by the following features:
a) at least one plug contact has an electrically conductive outer body, in the interior of which a permanent magnet is arranged, wherein the permanent magnet extends over a portion of the longitudinal extent of the outer body or over the entire longitudinal extent of the outer body,
   and/or
b) the connector has a sleeve-shaped body which extends externally around the plug contact or the plug contacts and is spaced from the plug contact or the plug contacts, wherein the sleeve-shaped body consists entirely or partly of a permanent magnet, in particular of at least one flat-tape magnetic strip and/or at least one magnetic film.

In this manner, it is possible to eliminate interference from electrical connectors better. For example, a respective plug contact can consist of a cylindrical sleeve-shaped tube section made from an electrically conductive material, e.g. silver or copper, or be coated with such an electrically conductive material on the outside. A permanent magnet in a pin shape (magnetic pin) can then be inserted in the interior of this tubular body.

In the following, any type of electrical component in which electrical voltage or current signals, which alternate over time, occur may be understood as an electrical component transmitting electrical signals. In particular, these may also be understood to include electromechanical and electronic components. For example, electrical connectors, electrical lines, electrical circuits, e.g. in the form of populated printed circuit boards, or individual electrical or electronic components such as microprocessors are also understood as such components.

A signal noise is generally understood to mean a disturbance with a wide nonspecific frequency spectrum. The signal noise can be generated by internal and external noise sources. Various causes of internal noise sources are already known from the literature, such as e.g. thermal noise, also known as Johnson noise, or shot noise. A further internal noise source is the generation-recombination noise in semiconductors. External noise sources are e.g. sources of electromagnetic interference (EMC), e.g. power lines, radio transmitters or electrical household appliances operated with 50 Hz AC voltage. The cosmic background noise is furthermore known as an external noise source.

The invention advantageously enables a significant reduction of the signal noise caused e.g. by the previously mentioned noise sources by means of a magnetic field generator that is arranged in a certain way with respect to the electrical component in an advantageous manner. The arrangement advantageously takes place in such a manner that the magnetic flux density (B) acting on the electrical component is considerably larger than the average magnetic flux density (B) generated by the electrical signals and originating from the electrical component. As a result of this, the magnetic field acts on the electrical component relatively strongly compared with the transported electrical signals and the noise components contained therein or compared with the average magnetic field induced by the signals or noise components over time. The relatively strong magnetic field effects an evening out of the electron motion of the electrical signal in the electrical component and also an evening out of the electron motions in the atoms of the material of the electrical component, as a result of which the noise components generated by internal noise sources are reduced in particular. Advantageously, the relatively strong magnetic field additionally shields the electrical component placed inside the magnetic field from the external sources of interference, so that the noise components of external noise sources in the signal are reduced. Overall, a reduction of the signal noise by at least 85 dB can be achieved as a result of this.

Advantageously, the electrical component is arranged rigidly compared to the magnetic field generator. As a result of this, a relative movement between the electrical component and the magnetic field generator is avoided.

Advantageously, the magnetic field generator here forms an effective shielding arrangement for the electrical component for shielding the electrical component against external radiated interference.

According to the invention, a magnetic force field is generated around the electrical component, which shields external radiated interference, as the energy of the sources of interference that are usually present is lower than the energy of the magnetic field in the region of the electrical component. Due to the magnetic force field, there is additionally a quality improvement in the electrical component, e.g. in the electronics, in cables and plugs, as these components can operate with greater freedom from interference and even the finest signals can be transmitted therein.

It was discovered that the noise-reducing advantageous properties of the invention already become perceptible at a magnetic flux density of B=0.5 tesla in conventional hi-fi apparatuses. A reduction of the signal noise is particularly advantageously achieved for magnetic flux densities in the range of B=1.29 to 1.42 teslas.

Advantageously, the magnetic field generator generates a substantially static magnetic field. The magnetic field generator can advantageously be designed e.g. as a permanent magnet or have a permanent magnet. Compared to electromagnets, permanent magnets have the advantage that they do not require the supply of electrical energy to generate the static magnetic field. Therefore, permanent magnets can easily be used for realizing the invention in areas in which there is no power supply available for the generation of the magnetic field. Additionally, a permanent magnet also requires no electrical energy, so permanent magnets are also advantageous with regard to a low energy consumption.

In this manner, inductive interference into the respective electrical component can be reliably avoided, which is of great importance in particular for the field of signal cables for metrology (measuring cables), signal cables for consumer electronics (audio/video cables) and for electronic components and printed circuit boards. Due to the use of flat-tape magnetic strips and/or magnetic film with magnetic fields of different strengths, it is possible to realize a shielding for electronic components with respect to one another and also outwardly. Also, the individual electronic component can be shielded against inductive interference by such flat-tape magnetic strips and/or magnetic films in that it is covered by the flat-tape magnetic strip and/or the magnetic film or is encased therewith. In the case of a plurality of electronic components on a printed circuit board, a shielding of an entire printed circuit board is possible by the positioning of one or more flat-tape magnetic strips and/or magnetic films next to one another and/or above one another.

The flat-tape magnetic strips and/or magnetic films can be configured in various magnetic strengths. For example, they may contain ferrite magnets and/or neodymium magnets. Both types of magnet can be used to adapt the magnetic field strength to the conditions individually.

In cable systems, it is likewise possible by means of the arrangement of flat-tape magnetic strips and/or magnetic films above or below the cable material to ensure the shielding of the single conductors with respect to one another. As a result of this, the crosstalk between the single conductors is minimized. In addition, the signal noise is reduced considerably. Also, influences from outside due to electrical inductions or other interference from the environment at the electrical components can clearly be minimized.

Due to the introduction of the ferrofluid into the cable interior, an inductive shielding of the single conductors with respect to the environment and with respect to one another can likewise be realized. If a static magnetic field is additionally generated outside the electrical cable, e.g. by the ring magnets arranged outside on the electrical cable or a magnetic film or flat-tape magnetic strip arranged thereon, the shielding effect can be further improved. Due to the ferrofluid, fine-core single conductors are also inductively shielded from one another and there is no more dominant crosstalk between the single conductors. The signal noise is also reduced considerably here. In this manner, the finest signals can also be reliably transmitted in the electronics and in cable systems. This results in a significant improvement of the clarity in the signal reproduction. As a result, it is possible to process and to evaluate signals which are no longer processible in a meaningful manner without these improvements.

The invention is explained in more detail below with reference to exemplary embodiments and using drawings.

In the drawings

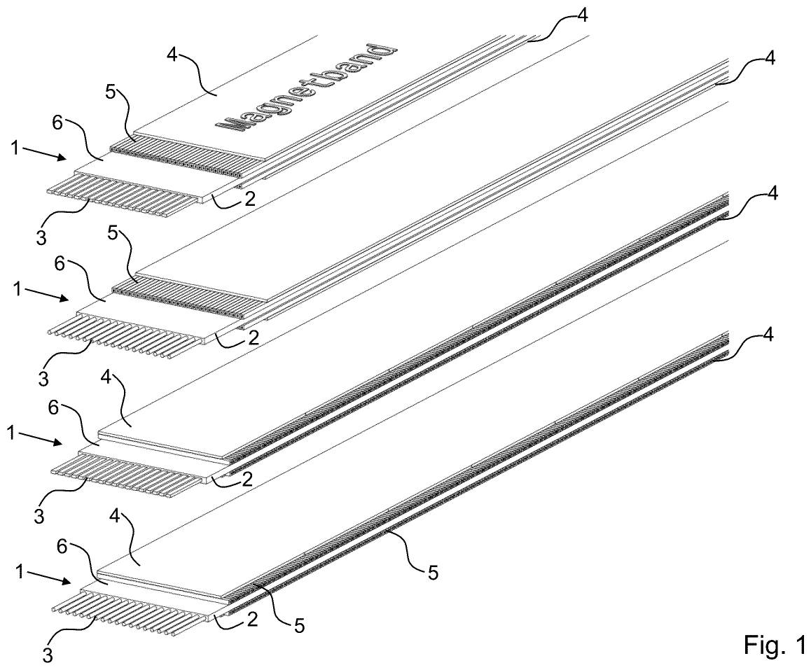

FIG. 1 shows various embodiments of magnetically shielded ribbon cables,

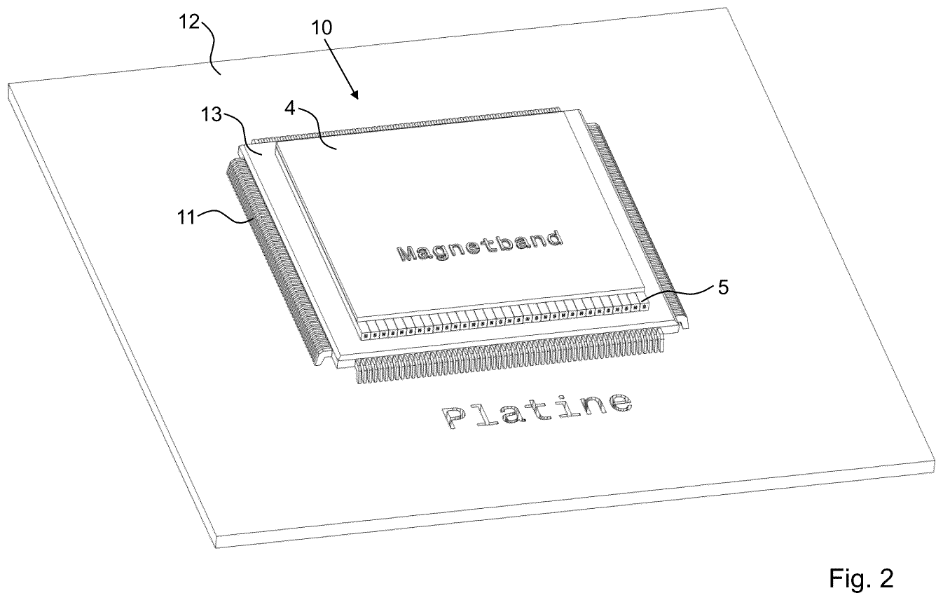

FIG. 2 shows a magnetically shielded integrated semiconductor component,

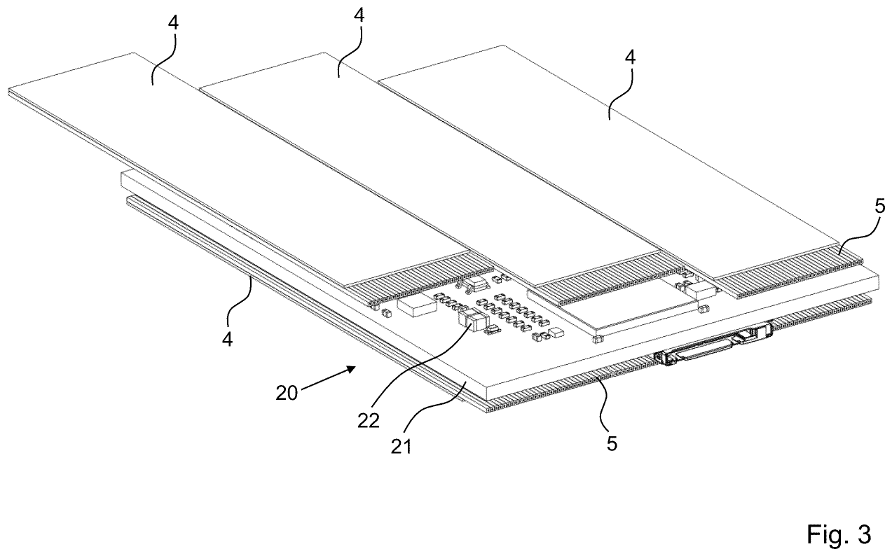

FIG. 3 shows a magnetically shielded electrical circuit arrangement,

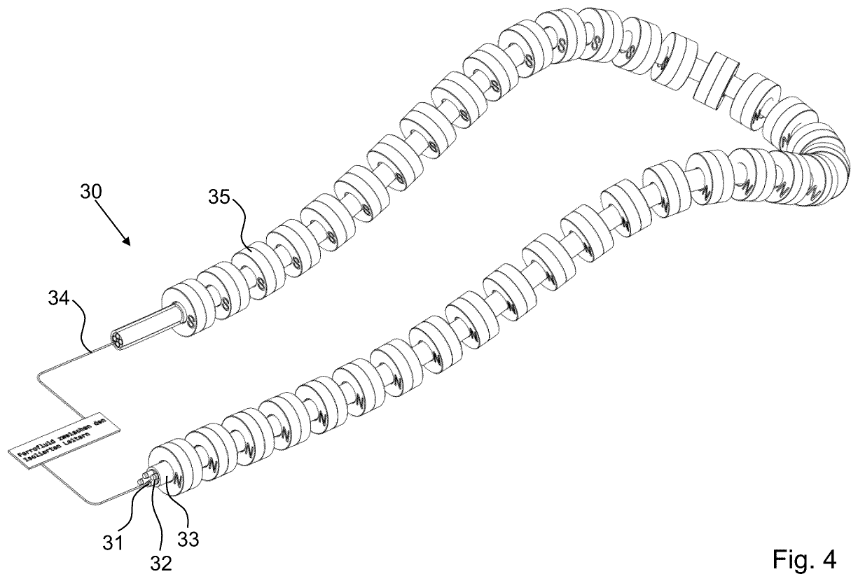

FIG. 4 shows a magnetically shielded electrical cable,

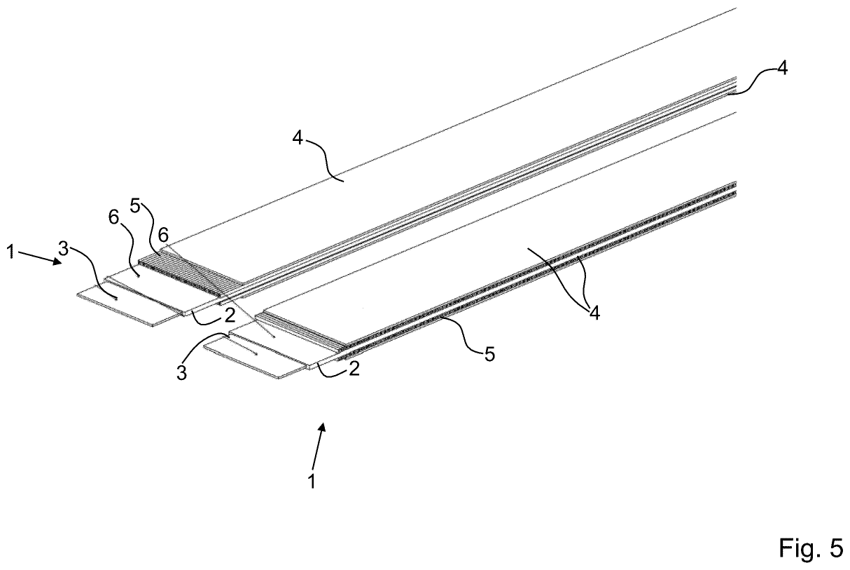

FIG. 5 shows further embodiments of magnetically shielded ribbon cables,

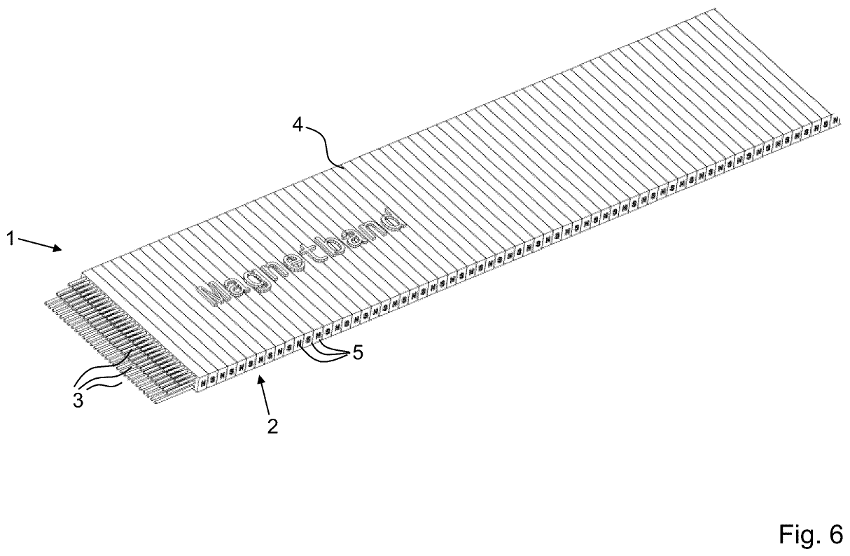

FIG. 6 shows a ribbon cable having electrical conductors integrated in a flat-tape magnetic strip,

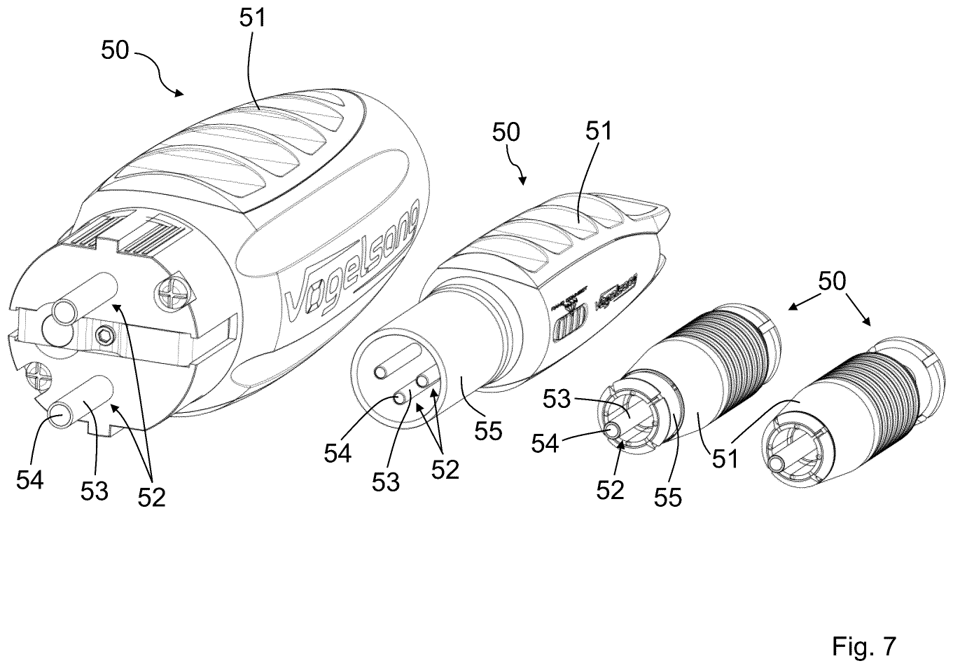

FIG. 7 shows electrical connectors in various embodiments,

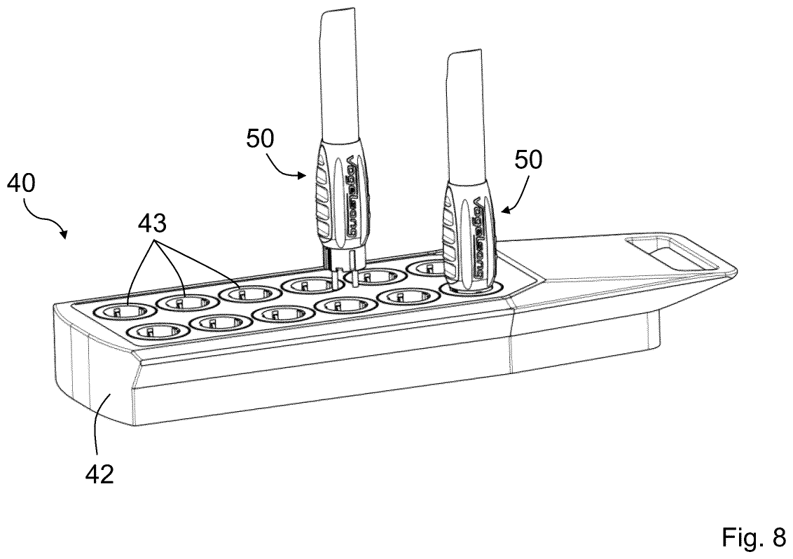

FIGS. 8-10 show an electrical power outlet strip in various views.

FIG. 1 shows respective devices 1 which in each case have a ribbon cable 2. The ribbon cable 2 has a multiplicity of electrical conductors 3 which are arranged next to one another and insulated with respect to one another and which are sheathed by insulating material 6. Magnetic shielding arrangements in the form of a flat-tape magnetic strip 4 and/or a magnetic film are arranged on both flat sides of the ribbon cable 2. The flat-tape magnetic strip 4 and/or the magnetic film has individual magnetic strips which are arranged next to one another and which are designed as permanent magnets of different polarity and arranged next to one another in an alternating manner. The two devices 1 illustrated at the top are here provided with flat-tape magnetic strips 4 in which the individual magnets 5 extend in a strip-shaped manner in the longitudinal direction next to one another. In the lower two devices 1, the magnets 5 are arranged orthogonally thereto, i.e. they extend in a strip-shaped manner next to one another transversely to the longitudinal direction of the ribbon cable 2.

FIG. 2 shows an integrated semiconductor component 10, e.g. a microprocessor, having a housing 13 and a multiplicity of connecting pins 11. For example, the connecting pins 11 of the semiconductor component 10 can be soldered on a printed circuit board 12. A magnetic shielding arrangement in the form of a flat-tape magnetic strip 4 and/or a magnetic film is arranged on the semiconductor component 10 or on its housing 13. One can also again here see the individual magnets 5 which are arranged next to one another in a strip-shaped manner and which are arranged there with alternation of different polarities.

FIG. 3 shows an electrical circuit arrangement 20 having a printed circuit board 21 and electrical and/or electronic components 22 arranged thereon. A magnetic shielding arrangement is arranged on the electrical circuit arrangement 20, here in the form of a plurality of flat-tape magnetic strips 4 and/or magnetic films which are arranged next to one another. One can also in turn here see the strip-shaped magnets 5 which are arranged next to one another and which are arranged next to one another in alternating polarity.

FIG. 4 shows an electrical cable 30 having a plurality of single electrical conductors 31 which are in each case arranged in an inner insulation layer 32 that sheathes the individual electrical conductors. An outer insulation layer 33 is also present, which encloses the outer insulation layers 32 of the electrical conductors 31. In addition, a ferrofluid 34 is arranged inside each of the inner insulation layers 32 and/or between the inner insulation layers 32 and the outer insulation layers 33. The electrical cable 30 is additionally encased on the outside by a magnet arrangement 35. The magnet arrangement 35 can be formed by a multiplicity of ring magnets arranged one behind the other and/or by at least one flat-tape magnetic strip and/or one magnetic film.

FIG. 5 shows an embodiment of devices 1 having in each case a ribbon cable 2 which has only one single electrical conductor 3 in the form of a flat sheet-metal strip which extends substantially over the entire width of the ribbon cable 2. The electrical conductor 3 is in turn sheathed with an insulation layer 6. Magnetic shielding arrangements in the form of a flat-tape magnetic strip 4 and/or a magnetic film are arranged on both flat sides of the ribbon cable 2. The flat-tape magnetic strip 4 and/or the magnetic film has individual magnetic strips which are arranged next to one another and which are designed as permanent magnets of different polarity and arranged next to one another in an alternating manner. The device 1 illustrated at the top is here provided with flat-tape magnetic strips 4 in which the individual magnets 5 extend in a strip-shaped manner in the longitudinal direction next to one another. In the lower device 1, the magnets 5 are arranged orthogonally thereto, i.e. they extend in a strip-shaped manner next to one another transversely to the longitudinal direction of the ribbon cable 2.

FIG. 6 shows a device 1 having a ribbon cable 2 in which the electrical conductors 3 are directly integrated into the substrate of the flat-tape magnetic strip 4. The single electrical conductors 3 in each case have an insulation layer sheathing them, which may consist of a lacquer for example. The electrical conductors 3 can be integrated into the substrate of the flat-tape magnetic strip directly during the production of the flat-tape magnetic strip 4. The flat-tape magnetic strip 4 has individual magnetic strips 5 which are arranged next to one another and which are designed as permanent magnets of different polarity and arranged next to one another in an alternating manner. The individual magnets 5 can extend in a strip-shaped manner next to one another in the longitudinal direction or orthogonally thereto, i.e. they can also be arranged in a strip-shaped manner next to one another transversely to the longitudinal direction of the ribbon cable 2.

FIG. 7 shows various embodiments of electrical connectors 50 in a perspective view in each case with a viewing direction onto the connector face. The connectors 50 can have a housing 51 and a plurality of plug contacts 52 in each case, as in e.g. the two connectors 50 illustrated on the left, or only one plug contact 52, as in the connector 50 illustrated on the right. The plug contacts 52 in each case have an electrically conductive outer body 53, e.g. in the form of a tube section, into the interior of which a permanent magnet 54, e.g. a magnetic pin, is inserted.

In addition, a respective connector 50 can have a sleeve-shaped body 55 sheathing the plug contacts 52, which consists entirely or partially of a permanent magnet material. The sleeve-shaped body 55 is spaced from the plug contacts 52, i.e. an intermediate space is present, in which a portion of the mating connector can be plugged. In this manner, magnet rings are formed around the plug contacts 52. As a result of this, shielding of the contact surfaces of the plug contacts 52 is ensured, as a static magnetic field forms in the intermediate space between the permanent magnet 54 and the outer magnet ring, i.e. the enclosing sleeve-shaped body 55.

As the two connectors 50 depicted on the right clarify, the connector 50 can also have a grip on its housing 51 that can be displaced in the longitudinal direction. Here, the sleeve-shaped body 55 which takes on the outer shielding can be arranged under the displaceable grip.

FIG. 8 shows an electrical power outlet strip 40, e.g. for the 220 V AC power supply, which has a housing 42 and a plurality of power outlets 43 that are accessible on the outside of the housing 42. An electrical connector 50, e.g. a connector 50 according to FIG. 7, can be plugged into each power outlet 43.

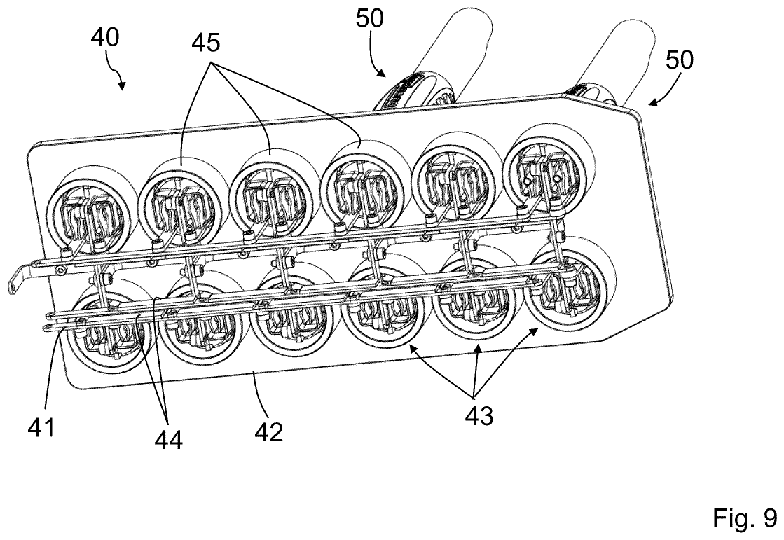

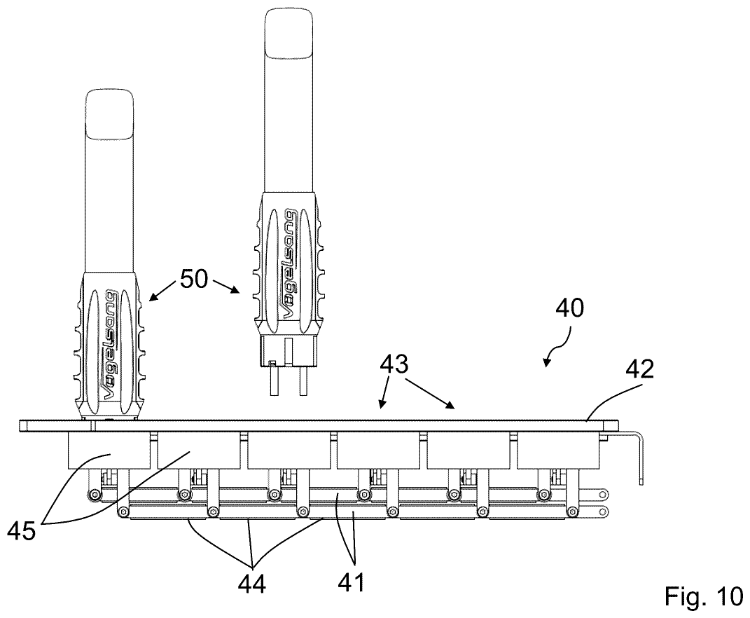

As FIGS. 9 and 10 clarify, the power outlet strip 40 has various components for magnetic shielding. Connecting lines 41 are arranged in the interior of the housing 42, which connecting lines connect the individual contacts of the power outlets 43 to a common supply line of the power outlet strip 40. These connecting lines 41 are provided with flat-tape magnetic strips 4 and/or magnetic films or with another type of permanent magnet 44. For the outer shielding, the contacts of the power outlets 43 can additionally be encased by a sleeve-shaped body 45 which at least partially or completely consists of permanent magnet material.

1. An electric device, comprising: (1) having
at least one electrical component; and
at least one flat-tape magnetic strip applied to the at least one electrical component and/or at least one magnetic film applied to the at least one electrical component, wherein the at least one electrical component is designed as:
a) a ribbon cable comprising one or more electrical conductors arranged next to one another in a width direction of the ribbon cable, and wherein the one or more electrical conductors are insulated with respect to one another, wherein each of the one or more electrical conductors are sheathed by insulating material, wherein the at least one flat-tape magnetic strip and/or the at least one magnetic film is or are arranged on at least one flat side of the ribbon cable or the on or more electrical conductors are embedded in a substrate of the at least one flat-tape magnetic strip and/or the at least one magnetic film, wherein the at least one flat-tape magnetic strip and/or the at least one magnetic film extends over at least a portion of a longitudinal extent of the ribbon cable or over an entire length of the ribbon cable,
and/or
b) an integrated semiconductor component comprising a housing made from an insulating material, wherein a semiconductor circuit is embedded in the insulating material, and wherein the integrated semiconductor component comprises a multiplicity of connecting pins or connecting pads which are contactable on an outside of the housing, wherein the at least one flat-tape magnetic strip and/or the at least one magnetic film is arranged on an upper side of the housing and extends over a portion of the upper side of the housing or over an entire upper side of the housing,
and/or
c) an electrical circuit arrangement comprising at least one printed circuit board with one or more and electrical and/or electronic components arranged thereon, wherein the at least one flat-tape magnetic strip and/or the at least one magnetic film is arranged on the electrical circuit arrangement and extends over a portion of a flat extent of the printed circuit board or over an entire flat extent of the printed circuit board,
and/or
d) an electrical power outlet strip comprising a housing, a plurality of power outlets having electrical contacts and connecting lines arranged in the housing which connect contacts of the power outlets to one or more supply lines, wherein the at least one flat-tape magnetic strip and/or the at least one magnetic film is arranged on one, several or all the connecting lines and extends over a portion of a flat extent of at least one connecting line or over an entire flat extent of the at least one connecting line.

2. The device as claimed in claim 1, wherein the ribbon cable has two flat sides and wherein the at least one flat-tape magnetic strip and/or the at least one magnetic film is arranged on the two flat sides of the ribbon cable and extends over at least a portion of the longitudinal extent of the ribbon cable or over the entire length of the ribbon cable.

3. The device as claimed in claim 1 wherein the one or more electrical conductors in the ribbon cable are formed from a flat sheet-metal material which has a substantially larger width than thickness.

4. The device as claimed in claim 1 wherein the one or more electrical conductors are each sheathed by an insulation layer formed by a lacquer.

5. The device as claimed in claim 1, wherein the at least one flat-tape magnetic strip and/or the at least one magnetic film is arranged on an underside of the housing and extends over a portion of the underside of the housing or over the entire underside of the housing.

6. The device as claimed in claim 1, wherein the at least one flat-tape magnetic strip and/or the at least one magnetic film is arranged on two sides of the electrical circuit arrangement and extends over a portion of the flat extent of the printed circuit board or over the entire flat extent of the printed circuit board.

7. The device as claimed in claim 1, wherein the electrical power outlet strip comprises one or more sleeve-shaped bodies, wherein each sleeve-shaped body extends in an annular manner around electrical contacts of a respective power outlet, wherein each sleeve-shaped body consists entirely or partly of a permanent magnet.

8. The device as claimed in claim 1 wherein the at least one flat-tape magnetic strip and/or the at least one magnetic film has individual strip-shaped magnets which are arranged next to one another and which are designed as permanent magnets of different polarity and arranged next to one another in an alternating manner.

9. An electrical cable, comprising:
at least one electrical conductor;
an internal insulation layer sheathing the at least one electrical conductor; and
one or more of the following features a), and b):
a) a ferrofluid is arranged inside the inner insulation layer on the at least one electrical conductor,
b) the internal insulation layer is sheathed by an additional outer insulation layer, wherein a ferrofluid is arranged between the internal insulation layer and the outer insulation layer.

10. The electrical cable as claimed in claim 9 further comprising a magnet arrangement arranged along a longitudinal extent on the electrical cable, wherein the magnet arrangement (35) in each case encloses the outer insulation layer or the internal insulation layer.

11. The electrical cable as claimed in claim 10 wherein the magnet arrangement comprises a multiplicity of ring magnets, and at least one flat-tape magnetic strip and/or a magnetic film.

12. An electrical connector for connection to a mating connector that is assigned as a mating part, wherein the electrical connector has one or more plug contacts wherein:
a) at least one plug contact has an electrically conductive outer body and an interior, wherein a permanent magnet is arranged in the interior, wherein the permanent magnet extends over a portion of a longitudinal extent of the outer body or over an entire longitudinal extent of the outer body, and/or
b) the electrical connector has a sleeve-shaped body which extends externally around the one or more plug contacts and is spaced from the one or more plug contacts, wherein the sleeve-shaped body (55) consists entirely or partly of a permanent magnet.

13. The electrical connector as claimed in claim 12 wherein the sleeve-shaped body has at least one permanent magnet over its entire circumference and/or over its entire longitudinal extent.

14. The electrical connector of claim 12 wherein the permanent magnet is configured as at least one flat magnetic strip and/or at least one magnetic film.

15. The electrical connector of claim 12 wherein the mating part is a power outlet strip comprising a housing, a plurality of power outlets having electrical contacts and connecting lines arranged in the housing which connect contacts of the power outlets to one or more supply lines, wherein the at least one flat-tape magnetic strip and/or the at least one magnetic film is arranged on one, several or all the connecting lines and extends over a portion of a flat extent of at least one connecting line or over an entire flat extent of the at least one connecting line.
